(19) United States
(12) Patent Application Publication
(10) Pub. No.: US 2012/0214304 A1
(43) Pub. Date: Aug. 23, 2012

(54) SEMICONDUCTOR DEVICE AND METHOD OF MANUFACTURING THE SAME

(75) Inventor: Dong Hoon KIM, Seoul (KR)

(73) Assignee: Hynix Semiconductor Inc., Icheon-si (KR)

(21) Appl. No.: 13/347,623

(22) Filed: Jan. 10, 2012

(30) Foreign Application Priority Data
Feb. 23, 2011 (KR) 10-2011-0016039

(51) Int. Cl. H01L 21/768

(52) U.S. Cl. 438/675; 257/E21.585

(57) ABSTRACT

The present invention provides a semiconductor device and a method of manufacturing the same. According to an embodiment of the present invention, a silicon oxide layer is formed over lower electrode contact plugs by using a selective oxidation process, wherein the silicon oxide layer has a thickness greater than an oxidized portion of an adjacent isolation layer (i.e., an isolation insulating layer). Accordingly, a concave contact area between a lower electrode and the lower electrode contact plug can be desirably be secured following etching of the silicon oxide layer in a subsequent process. Specifically, a width of the adjacent isolation layer does not need to be increased because sequential dry and wet etch processes expose the lower electrode contact plugs in a process of forming the lower electrodes.

### CROSS-REFERENCE TO RELATED APPLICATION

Priority to Korean patent application number 10-2011-0016039, filed on Feb. 23, 2011, which is incorporated by reference in its entirety, is claimed.

### BACKGROUND OF THE INVENTION

Embodiments of the present invention relate to a semiconductor device and a method of manufacturing the same. Recently, in case of a semiconductor device, such as DRAM, the area occupied by the device is reduced according to an increased degree of integration, whereas necessary capacitance needs to be maintained or increased. In general, a method of securing sufficient cell capacitance within a limited area may include, for example, a method of using a high-k material as a dielectric layer, a method of reducing the thickness of a dielectric layer, and a method of increasing the effective area of a lower electrode.

From among the methods, the method using a high-k material requires physical and temporal investment, such as the introduction of new equipment, a verification of reliability and mass production of a dielectric layer, and a low temperature of a subsequent process. Accordingly, the method of increasing the effective area of a lower electrode is chiefly used in actual processes because the existing dielectric layer may continue to be used and the process is relatively easily implemented.

The method of increasing the effective area of a lower electrode may include, for example, a method of forming lower electrodes of a 3-dimension (3-D) in a cylinder form or a fin form, a method of growing hemi-spherical grain (HSG) on the lower electrodes, and a method of increasing the height of the lower electrode. From among the methods, the method of growing HSG becomes hindrance when critical dimension (CD) of a certain level between the lower electrodes is secured and causes a bridge between the lower electrodes because HSG is sometimes peeled off. Accordingly, the method of growing HSG is difficult to be applied to semiconductor devices of 0.14 μm or lower in the design rule. For this reason, in order to improve cell capacitance, the method of forming lower electrodes of a 3-D and the method of increasing the height of lower electrode is chiefly adopted. Form among them, a widely known method is a method of forming lower electrodes in a cylinder form or a stack form.

In particular, in a known method of forming a cylinder type lower electrode, after a sacrificial insulating layer near the lower electrodes is indispensably removed, a dielectric layer is deposited on the lower electrodes. Here, dielectric material for the dielectric layer is deposited not only on the lower electrodes, but also between adjacent lower electrodes. Thus, the dielectric material and upper electrodes formed thereon are shared by the cells. If however, the dielectric material is shared as described above, capacitance (storage capacity) between the lower electrodes may interfere with each other, and the capacitance may be distorted.

FIGS. 1a and 1b are cross-sectional views showing a known semiconductor device and a method of manufacturing the same.

Referring to FIG. 1a, a first insulating layer 100 is formed over a semiconductor substrate.

After a photoresist layer is formed on the first insulating layer 100, photoresist patterns (not shown) are formed by performing exposure and development processes using a mask for forming storage node contact plugs. The storage node contact holes (not shown) are formed by etching the first insulating layer 100 using the photoresist patterns as an etch mask. Next, storage node contact plugs 110 are formed by filling the storage node contact holes with conductive material.

Next, a first sacrificial insulating layer 150 is formed. The first sacrificial insulating layer 150 has a stack structure of a phosposilicate glass (PSG) layer 130 and a tetraethly orthosilicate (TEOS) later 140.

A support layer 160 for a nitride floating cap (NFC) and a second sacrificial insulating layer 170 are formed over the first sacrificial insulating layer 150.

After a photoresist layer is formed on the second sacrificial insulating layer 170, photoresist patterns (not shown) are formed by performing exposure and development processes employing a lower electrode mask. Lower electrode holes 180 are formed by etching the second sacrificial insulating layer 170, the support layer 160 for an NFC, and the first sacrificial insulating layer 150, until the storage node contact plugs 110 are exposed by using the photoresist patterns as an etch mask.

Next, after a conductive material 190 is deposited over the lower electrode hole 180, the second sacrificial insulating layer 170, and the support layer 160 for an NFC, the conductive material 190 is etched back to form lower electrodes. In this case, if a pattern size of the first insulating layer 100 or an isolation layer (i.e., an isolation insulating layer) is increased, a bridge fail may be prevented between neighboring storage node contact plugs 110. A bridge fail occurs when the conductive material 190 is commonly coupled to the neighboring storage node contact plugs 110.

In contrast, when a pattern size reduces, it is difficult to form a contact hole, especially when an aspect ratio is high. In addition, when a pattern size reduces, contact resistance increases between the storage node contact plug 110 and the lower electrode because of the reduced a contact area, indicated by ‘A’.

Referring to FIG. 1b, if the critical dimension (CD) of the first insulating layer 100 or the isolation layer (i., an isolation insulating layer) is reduced in order to prevent the problem indicated by ‘A’, a bridge fail may occur between neighboring storage node contact plugs 110, as indicated by ‘B’.

As described above, in order to maximize capacitance of a cell for improving the refresh characteristic of the known cylinder type lower electrode, the height of the lower electrode is increased and an interval between the lower electrode contact plugs is reduced. In this case, there are problems in that a bridge phenomenon is generated between the lower electrodes and the contact area of the lower electrode contact plug and the lower electrode is difficult to secure.

### BRIEF SUMMARY OF THE INVENTION

The present invention provides a method of manufacturing a semiconductor device, including forming a first insulating layer over a semiconductor substrate, forming a contact plug between the first insulating layers, forming a second insulating layer on the contact plugs and the first insulating layers, wherein the second insulating layer formed on the contact plugs is thicker than the second insulating layer formed on the first insulating layers, forming a sacrificial insulating layer on the entire surface including the second insulating layers, forming first lower electrode holes by etching the sacrificial insulating layer until the second insulating layers are exposed, forming second lower electrode holes by removing the second insulating layers, and filling conductive material in the second and the first lower electrode holes and forming lower electrodes by etching back the conductive material.

A forming-a-contact-plug-between-the-first-insulating-layers preferably includes forming contact holes by etching the first insulating layers until the semiconductor substrate is exposed and filling conductive material in the contact holes.

The contact plugs preferably include doped polysilicon.

The second insulating layers preferably are formed by using a selective oxidation process.

The second insulating layers preferably include silicon oxide (SiO₂).

The method preferably further includes forming a third insulating layer on the second insulating layers and etching the third insulating layer until the first insulating layers are exposed, after forming the second insulating layers.

The method preferably further includes forming an etch-stop layer on the second insulating layers and the first insulating layers, after etching the third insulating layer.

An etching-the-third-insulating layer preferably is performed by using a dry etch method.

The method preferably further includes polishing the etch-stop layer, after forming the etch-stop layer.

The sacrificial insulating layer preferably has a stack structure of a phosposilicate glass (PSG) layer and a tetraethly orthosilicate (TEOS) layer.

The method preferably further includes sequentially forming a support layer for a nitride floating cap (NFC) and another sacrificial insulating layer, after forming the sacrificial insulating layer.

A forming-first-lower-electrode-holes-by-etching-the-sacrificial-insulating-layer preferably is performed by using a dry etch method.

A forming-second-lower-electrode-holes-by-removing-the-second-insulating-layers preferably is performed by using a wet etch method.

The conductive material preferably is formed by stacking a titanium (Ti) layer and a titanium nitride (TiN) layer.

### BRIEF DESCRIPTION OF THE DRAWINGS

FIGS. 1a and 1b are cross-sectional views showing a known semiconductor device and a method of manufacturing the same, and

FIGS. 2a to 2i are cross-sectional views showing a semiconductor device and a method of manufacturing the same according to an embodiment of the present invention.

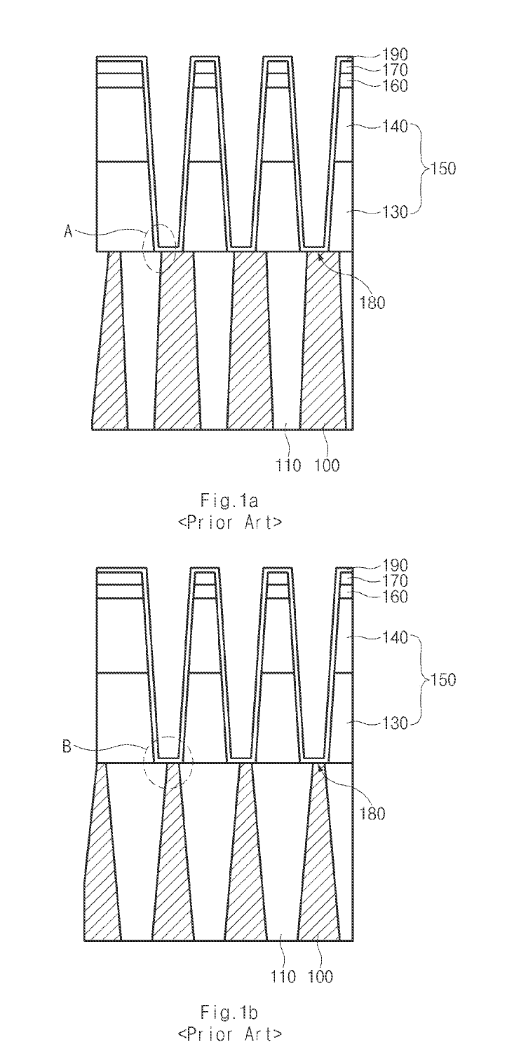

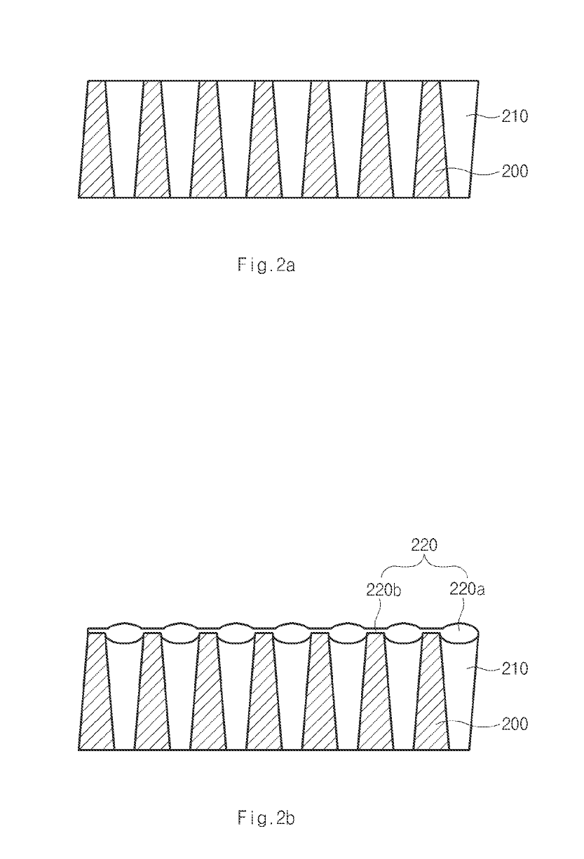

### DESCRIPTION OF EMBODIMENT

The present invention will be described more fully hereinafter with reference to the accompanying drawings, in which an exemplary embodiment of the invention is shown. As those skilled in the art would realize, the described embodiment may be modified in various different ways, all without departing from the spirit or scope of the present invention.

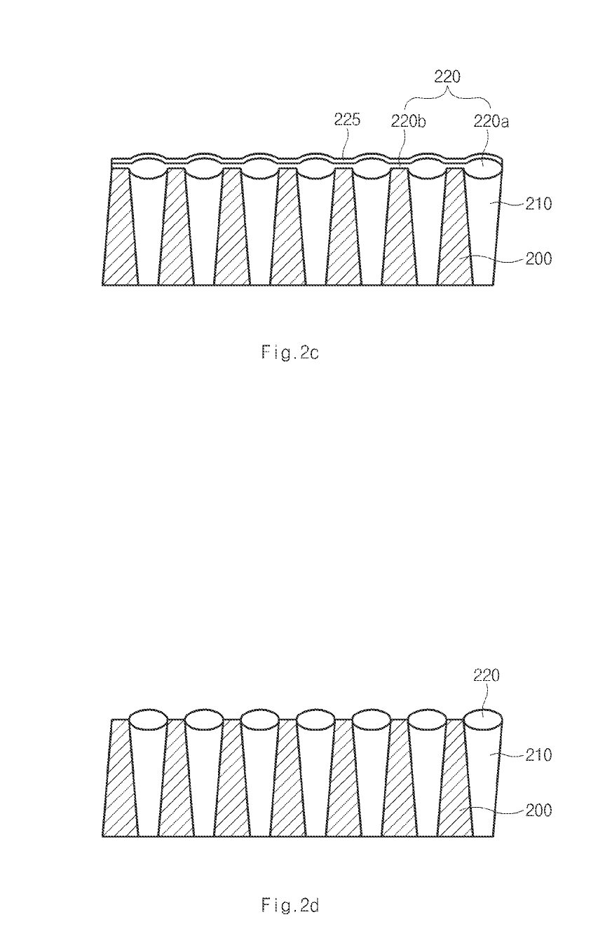

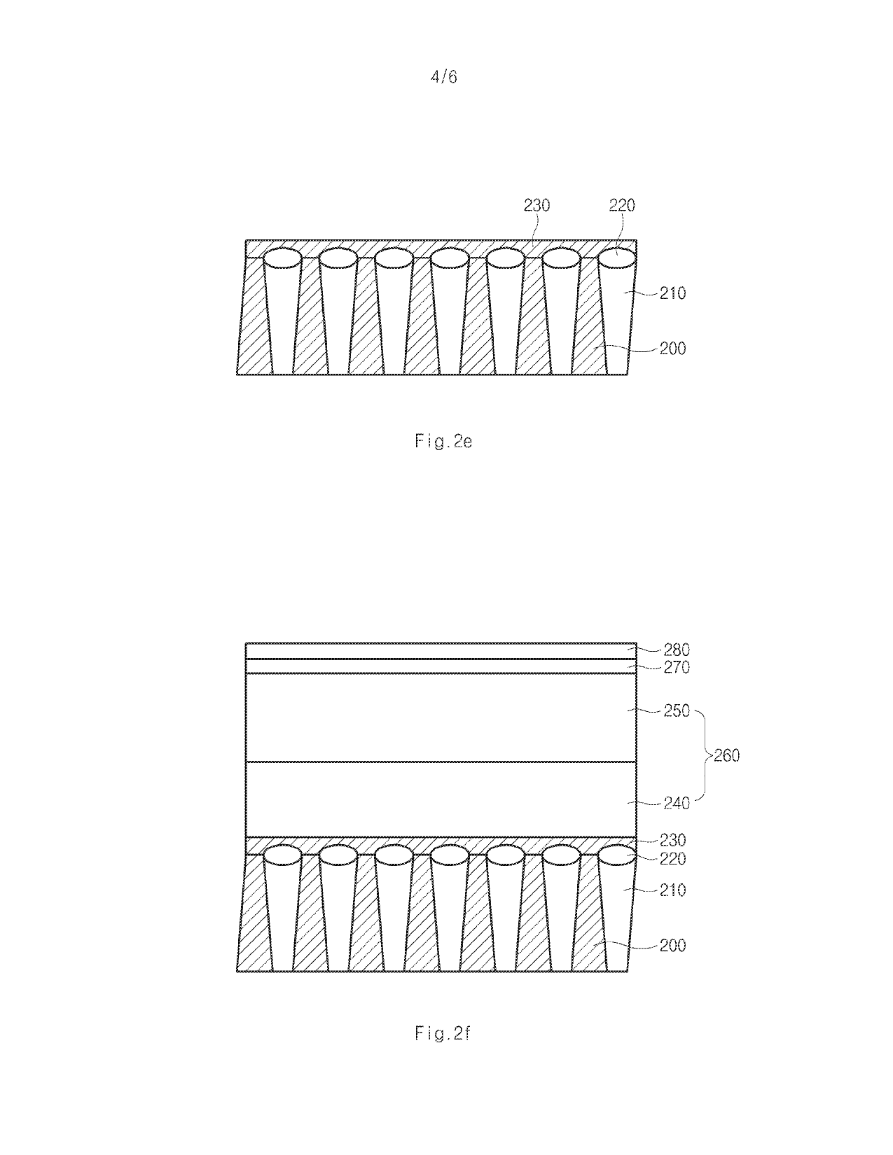

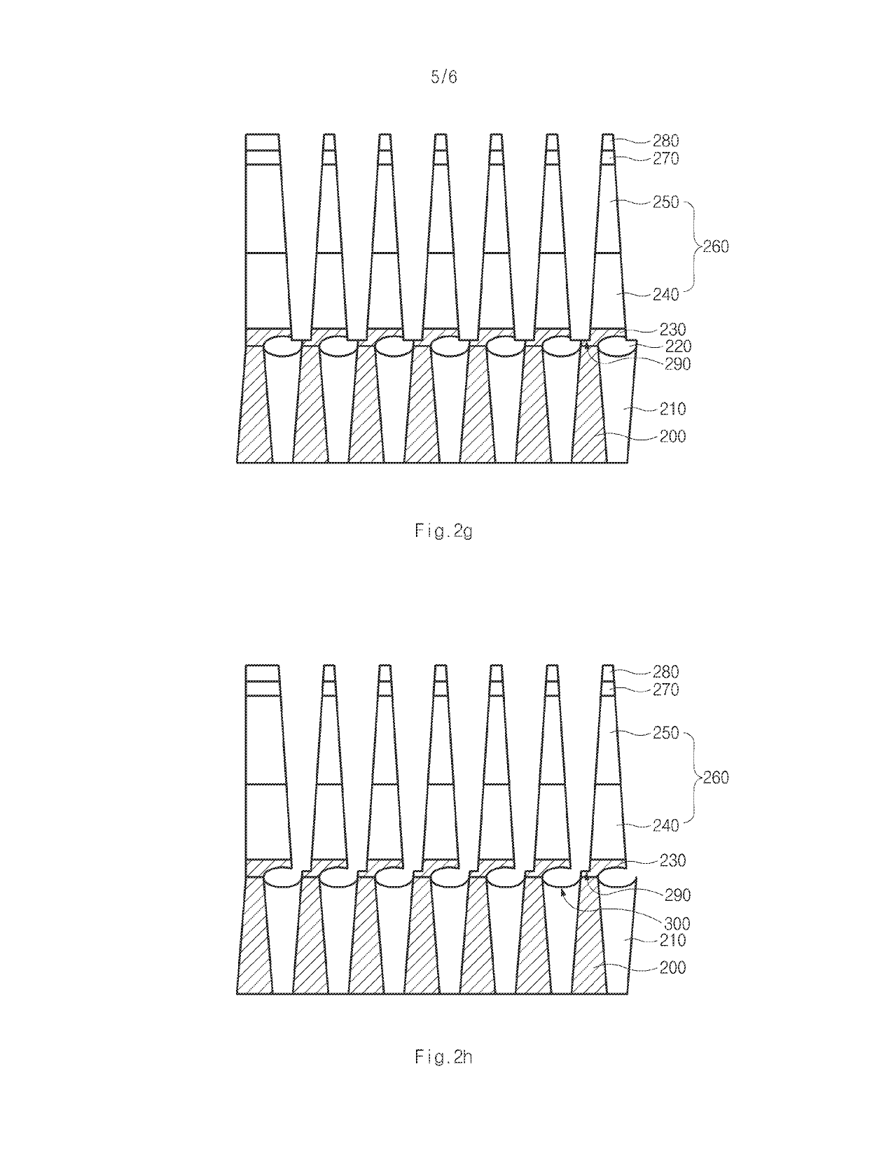

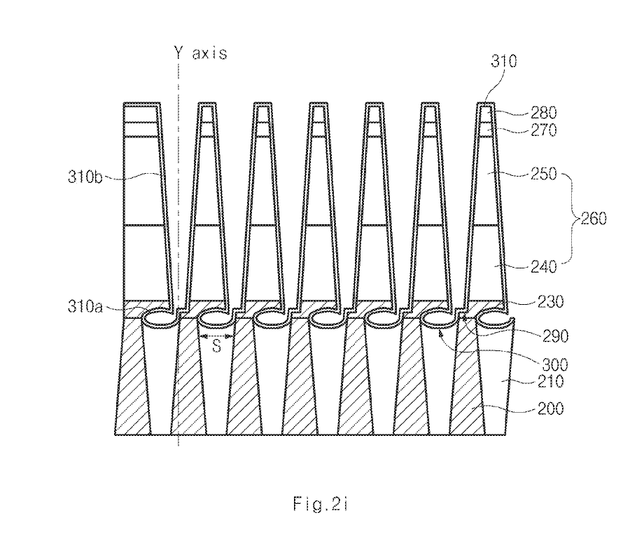

FIGS. 2a to 2i are cross-sectional views showing a semiconductor device and a method of manufacturing the same according to an embodiment of the present invention.

Referring to FIG. 2a, a first insulating layer 200 is formed over a semiconductor substrate. The first insulating layer 200 may include a nitride layer.

A photoresist layer is formed on the first insulating layer 200. Next, photoresist patterns (not shown) are formed by performing exposure and development processes using a mask for forming storage node contact plugs.

Storage node contact holes (not shown) are formed by etching the first insulating layer 200 using the photoresist patterns as an etch mask. Storage node contact plugs 210 are formed by filling the storage node contact holes with conductive material.

The conductive material may be polysilicon into which impurities have been implanted. Impurities of PH₃ may be used.

Referring to FIG. 2b, a second insulating layer 220 is formed on the storage node contact plugs 210 and the first insulating layers 200, by performing a selective oxidation process. Here the second insulating layer 220 formed on the storage node contact plugs 210, is thicker than the second insulating layer 220 formed on the first insulating layers 200. This is because a ratio of oxidation is higher in the polysilicon of the storage node contact plugs 210 than in the nitride layer of the first insulating layer 200 under the same condition and time in the oxidation process. The second insulating layer 220 may include silicon oxide (SiO₂).

Referring to FIG. 2c, after the selective oxidation process is performed, a third insulating layer 225 may be further deposited on the surface including the storage node contact plugs 210. The third insulating layer 225 may include oxide.

Referring to FIG. 2d, the third insulating layer 225 is etched until the second insulating layer 220 is exposed. The third insulating layer 225 may be etched by using a dry etch method. The dry etch method is advantageous in etching with a high selectivity in a specific direction.

Referring to FIG. 2e, an etch-stop layer 230 is formed on the second insulating layers 220 and the first insulating layers 200. In this case, it is preferred that the etch-stop layer 230 include nitride. The etch-stop layer 230 is polished by using a method, such as chemical mechanical polishing (CMP).

Referring to FIG. 2f, a first sacrificial insulating layer 260 is formed on the etch-stop layer 230. The first sacrificial insulating layer 260 may have a stack structure of a phosposilicate glass (PSG) layer 240 and a tetraethly orthosilicate (TEOS) layer 250.

A support layer 270 for a nitride floating cap (NFC) and a second sacrificial insulating layer 280 are formed over the first sacrificial insulating layer 260. The support layer 270 for a NFC may include nitride, and the second sacrificial insulating layer 280 may be formed of a TEOS layer.

Referring to FIG. 2g, a photoresist layer is formed on the second sacrificial insulating layer 280. Next, photoresist patterns (not shown) are formed by performing exposure and development processes employing a lower electrode mask.

First lower electrode holes 290 are formed by etching the second sacrificial insulating layer 280, the support layer 270 for a NFC, the first sacrificial insulating layer 260, and the etch-stop layer 230, using the photoresist patterns as an etch mask until the second insulating layers 220 on the storage node contact plugs 210 are exposed. The etch method used to form the first lower electrode holes 290 be a dry etch method.

Referring to FIG. 2h, second lower electrode holes 300 are formed by etching the second insulating layers 220. The second insulating layers 220 be etched by using a wet etch method. Here, the wet etch method can be an isotropic etch method. The contact area of the storage node contact plug 210 and a lower electrode can be enlarged by using the wet etch method.

Referring to FIG. 2i, conductive material 310 is deposited on the second and the first lower electrode holes 300 and 290, on the second sacrificial insulating layer 280, on the support layer 270 for a NFC, and on the first sacrificial insulating layer 260. Although not shown in FIG. 2i, in a next step lower electrodes are formed by etching back the conductive material 310 until the second sacrificial insulating layer 280 is exposed.

In this embodiment, a semiconductor device according to an embodiment of the present invention includes a storage node contact plug (210), a first insulating layer (200) formed next to the storage node contact (210), and a lower electrode pattern (310) including an upper portion (310b) and an expanded lower portion (310a).

The expanded lower portion (310a) extends from the upper portion into the storage node contact plug (210).

The lower electrode pattern (310) is coupled to the storage node contact plug (210) through the expanded lower portion (310a)

The upper portion (310b) may be in a bulb shape, but not limited thereto. The upper portion (310b) may be in a cylinder shape, but is not limited thereto. The expanded lower portion (310a) is extended from an edge of the upper portion (310b) disposed toward the storage node contact plug (210)

The upper portion is configured symmetrically with respect to a given axis (Y axis) perpendicular to a surface of the storage node contact plug (210). The expanded lower portion is configured asymmetrically with respect to the given axis.

In case when the storage node contact plug (210) has a concave contact surface area (S), the expanded lower portion (310a) may be in substantially complete contact with the storage node contact plug (210) throughout the concave contact surface area (S)

A semiconductor device according to an embodiment of the present invention may be formed by the following processes.

A storage node contact plug (210) defines a first insulating layer (200). See FIG. 2a. A second insulating layer (260) is formed over the storage node contact plug (210) and the first insulating layer (200). See FIG. 2a. A first lower electrode hole (290) is formed to expose the storage node contact plug (210). See FIG. 2g.

A second lower electrode hole (300) extends from the first lower electrode hole (290) into the storage node contact plug (210). See FIG. 2h. A lower electrode (310) is formed along an inner surface of the first and the second lower electrode holes (290, 300). See FIG. 2i.

The lower electrode pattern (310) includes an upper portion (310b) formed along the inner surface of the first lower electrode hole (290), and an expanded lower portion (310a) formed along the inner surface of the second lower electrode hole (300). See FIG. 2i. The lower electrode pattern (310) is coupled to the storage node contact plug (210) through the expanded lower portion (310a).

After the step of forming the storage node contact plug (210) to define the first insulating layer (200), surfaces of the storage node contact plug (210) and the first insulating layer (200) may be oxidized to form first and second selective oxide films (220a, 220b) over the storage node contact plug (210) and the first insulating layer (200), respectively. See FIG. 2b.

A thickness of the first selective oxide film (220a) is greater than that of the second selective oxide film (220b). See FIG. 2b. The second lower electrode hole (300) is formed by removing the first selective oxide film (220a). See FIG. 2h.

The step of removing the first selective oxide film (220a) to form the second lower electrode hole (300) may be performed by a wet etching process. See FIG. 2h. The step of forming the first lower electrode hole (290) is performed by a dry etching process. See FIG. 2g.

As described above, according to embodiments of the present invention, an oxide silicon layer is formed over lower electrode contact plugs by using a selective oxidation process, wherein the oxide silicon layer is thicker than an adjacent isolation layer (i.e., an isolation insulating layer). Accordingly, the contact between a lower electrode and the lower electrode contact plug can beneficially be secured in a subsequent process.

Furthermore, a process of increasing the width of the adjacent isolation layer does not need to be performed, because dry and wet etch processes are sequentially performed until the lower electrode contact plugs are exposed in a process of etching an insulating layer in order to form the lower electrodes.

The above embodiment of the present invention is illustrative and not limitative. Various alternatives and equivalents are possible. The invention is not limited by the type of deposition, etching polishing, and patterning steps described herein.

Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

1. A method of manufacturing a semiconductor device, comprising:
forming first insulating layer over a semiconductor substrate;
forming a contact plug between the first insulating layers;
forming a second insulating layer over the contact plug and the first insulating layer, wherein the second insulating layer formed over the contact plug has a greater thickness than the second insulating layer formed over the first insulating layer;
forming a sacrificial insulating layer over a surface including the second insulating layer;
forming a first lower electrode hole by etching the sacrificial insulating layer until the second insulating layer are exposed;
forming a second lower electrode hole by removing the second insulating layer; and
filling conductive material in the second and the first lower electrode holes and forming a lower electrode by etching back the conductive material.

2. The method according to claim 1, wherein a forming-a-contact-plug-between-the-first-insulating-layers includes:
forming contact holes by etching the first insulating layers until the semiconductor substrate is exposed; and
filling conductive material in the contact holes.

3. The method according to claim 1, wherein the contact plug includes doped polysilicon.

4. The method according to claim 1, wherein the second insulating layer is formed by using a selective oxidation process.

5. The method according to claim 1, wherein the second insulating layer includes silicon oxide (SiO2).

6. The method according to claim 1, the method further comprising:
forming a third insulating layer over the second insulating layer; and
etching the third insulating layer until the first insulating layers are exposed, after forming the second insulating layer.

7. The method according to claim 6, the method further comprising forming an etch-stop layer over the second insulating layer and the first insulating layers, after etching the third insulating layer.

8. The method according to claim 6, wherein an etching-the-third-insulating layer is performed by using a dry etch method.

9. The method according to claim 7, the method further comprising polishing the etch-stop layer, after forming the etch-stop layer.

10. The method according to claim 1, wherein the sacrificial insulating layer has a stack structure of a phosposilicate glass (PSG) layer and a tetraethly orthosilicate (TEOS) layer.

11. The method according to claim 1, the method further comprising forming a support layer for a nitride floating cap (NFC) and a second sacrificial insulating layer over the sacrificial insulating layer.

12. The method according to claim 1, wherein a forming-first-lower-electrode-holes-by-etching-the-sacrificial-insulating-layer is performed by using a dry etch method.

13. The method according to claim 1, wherein a forming-second-lower-electrode-holes-by-removing-the-second-insulating-layers is performed by using a wet etch method.

14. The method according to claim 1, wherein the conductive material is formed by stacking a titanium (Ti) layer and a titanium nitride (TiN) layer.

15-19. (canceled)

20. A method for forming a semiconductor device comprising:
forming a storage node contact plug to define a first insulating layer;
forming a second insulating layer over the storage node contact plug and the first insulating layer;
forming a first lower electrode hole to expose the storage node contact plug;
forming a second lower electrode hole extending from the first lower electrode hole into the storage node contact plug; and
forming a lower electrode along an inner surface of the first and the second lower electrode holes.

21. The method for forming a semiconductor device of claim 20,
wherein the lower electrode pattern includes:
an upper portion formed along the inner surface of the first lower electrode hole, and
an expanded lower portion formed along the inner surface of the second lower electrode hole, and
wherein the lower electrode pattern is coupled to the storage node contact plug through the expanded lower portion.

22. The method for forming a semiconductor device of claim 20, the method further comprising, after the step of forming the storage node contact plug to define the first insulating layer, oxidizing surfaces of the storage node contact plug and the first insulating layer to form first and second selective oxide films over the storage node contact plug and the first insulating layer, respectively,
wherein a thickness of the first selective oxide film is greater than that of the second selective oxide film, and
wherein the second lower electrode hole is formed by removing the first selective oxide film.

23. The method for forming a semiconductor device of claim 22
wherein the step of removing the first selective oxide film to form the second lower electrode hole is performed by a wet etching process.

24. The method for forming a semiconductor device of claim 20,
wherein the step of forming the first lower electrode hole is performed by a dry etching process.
